(19) United States
(12) Patent Application Publication
(10) Pub. No.: US 2026/0354250 A1
(43) Pub. Date: Nov. 5, 2026

(54) SLANTED DIE PAD FOR SPACE OPTIMIZATION ON A SEMICONDUCTOR DIE

(71) Applicant: Micron Technology, Inc., Boise, ID (US)

(72) Inventors: Deborah Odette MOIZIN, Singapore (SG); Amirul Afiq HUD, Iskandar Puteri (MY)

(21) Appl. No.: 19/553,497

(22) Filed: Mar. 2, 2026

Related U.S. Application Data
(60) Provisional application No. 63/798,791, filed on May 2, 2025.

(51) Int. Cl. H10W 72/90; H10W 90/00; H10W 72/00; H10W 72/50; H10W 90/10

(52) U.S. Cl. CPC H10W 72/9445; H10W 72/926; H10W 90/753; H10W 90/754; H10W 72/019; H10W 72/5473; H10W 90/10

(57) ABSTRACT

Implementations described herein relate to various semiconductor device assemblies. In some implementations, a semiconductor device assembly includes a semiconductor die that includes a die pad surface having a first die edge that extends parallel to a first axis and a second die edge that extends parallel to a second axis that is perpendicular to the first axis; and a plurality of die pads arranged on the die pad surface, the plurality of die pads having a slanted orientation relative to the first axis and the second axis. The plurality of die pads are arranged along a first edge region of the first die edge. Each die pad of the plurality of die pads has a longitudinal axis that extends at an angle between 40 and 50 degrees relative to the first die edge.

### CROSS-REFERENCE TO RELATED APPLICATION

This Patent Application claims priority to U.S. Provisional Patent Application No. 63/798,791, filed on May 2, 2025, entitled “SLANTED DIE PAD FOR SPACE OPTIMIZATION ON A SEMICONDUCTOR DIE,” and assigned to the assignee hereof. The disclosure of the prior Application is considered part of and is incorporated by reference into this Patent Application.

### TECHNICAL FIELD

The present disclosure generally relates to semiconductor devices and methods of forming semiconductor devices. For example, the present disclosure relates to semiconductor dies with slanted die pads for space optimization.

### BACKGROUND

A semiconductor package may include a semiconductor substrate, one or more semiconductor electronic components coupled to and/or embedded in the semiconductor substrate, and a casing formed over the semiconductor substrate to encapsulate the one or more semiconductor electronic components. The one or more semiconductor electronic components may be interconnected by electrical interconnects to form one or more semiconductor devices, such as one or more integrated circuits (ICs) (e.g., one or more dies or chips). For example, the semiconductor electronic components and the electrical interconnects may be fabricated on a semiconductor wafer to form one or more ICs before being diced into dies or chips and then packaged. A semiconductor package may be referred to as a semiconductor chip package that includes one or more ICs. A semiconductor package protects the semiconductor electronic components and the electrical interconnects from damage and includes a mechanism for connecting the semiconductor electronic components and the electrical interconnects to external components (e.g., a circuit substrate), such as via balls, pins, leads, contact pads, or other electrical interconnect structures. A semiconductor device assembly may be or may include a semiconductor package, multiple semiconductor packages, and/or one or more components of a semiconductor package (e.g., one or more semiconductor devices with or without a casing).

An electronic system assembly may include multiple semiconductor packages electrically coupled to a carrier substrate (e.g., circuit substrate). An electronic system assembly may include additional system components electrically coupled to the carrier substrate. The carrier substrate may include electrical interconnects and conductive paths used for interconnecting system components, including the multiple semiconductor packages and other system components of the electronic system assembly. Accordingly, the multiple semiconductor packages may be electrically connected to each other and/or to one or more additional system components via the carrier substrate to form the electronic system assembly. By way of example, other system components may include passive components (e.g., storage capacitors), processing units (e.g., a central processing unit (CPU), a graphics processing unit (GPU), a microprocessor, and/or a microcontroller), control units (e.g., a microcontroller, a memory controller, and/or a power management controller), or one or more other electronic components.

### BRIEF DESCRIPTION OF THE DRAWINGS

FIG. 1 is a diagram of an example apparatus that may be manufactured using techniques described herein.

FIG. 2A is a top view of the semiconductor die according to one or more implementations.

FIG. 2B is a top view of the semiconductor die according to one or more implementations.

FIG. 3 is a top view of a semiconductor device assembly according to one or more implementations.

FIG. 4 is a top view of a semiconductor device assembly according to one or more implementations.

FIG. 5 is a flowchart of an example method of forming an integrated assembly or semiconductor die having slanted die pads.

### DETAILED DESCRIPTION

In the field of semiconductor devices, die size of a semiconductor die and optimizing an area of the semiconductor die are critical factors that impact overall device performance and efficiency. With each new generation of dies, particularly for NAND memory dies, there is a pressing need to enhance power delivery and signal performance while maintaining or reducing an overall footprint of the die. However, as the die size becomes smaller, the challenge of integrating bond pads (e.g., die pads), without a reduction in quantity, and wire bonds within the existing or reduced space becomes increasingly complex. The current approaches often involve suboptimal space utilization and limit the number of bond pads and/or wire bonds due to die size constraints. Additionally, there is a growing demand for higher power and improved signal delivery in dies, which presents a technical hurdle to achieve improved device performance without increasing the die size.

Some implementations described herein provide a semiconductor device assembly that optimizes space on a semiconductor die by incorporating a slanted die pad orientation. The semiconductor die includes a plurality of die pads arranged in a slanted orientation relative to the edges of a die pad surface. The die pad surface may be a main surface (e.g., a top surface) on which die pads are arranged. Each die pad has a longitudinal axis that extends at an angle, specifically between 40 and 50 degrees, with a preferred angle of 45 degrees, relative to a nearest die edge.

In some aspects, the slanted die pads enable overlapping configurations when viewed from a particular axis, allowing for a denser arrangement of die pads and bond wires. The slanted die pads may include supply pads (e.g., die pads configured to configured for power or ground) and/or signal pads (e.g., die pads configured for data signals). Furthermore, a method of manufacturing such a semiconductor device assembly includes forming the die pads with the described slanted orientation and bonding multiple bond wires to the supply pads.

In this way, the slanted die pad configuration effectively addresses the problem of space limitation on a semiconductor die by enabling more bond pads and wire bonds to be included within the same or a reduced die size. This configuration may provide improved power density and signal integrity due to an increased number of pads and wire bonds. Additionally, this configuration may enable a potential reduction in die size and an increase in functional density without expanding a footprint of the semiconductor die. In this way, quality and/or reliability of the semiconductor device is improved.

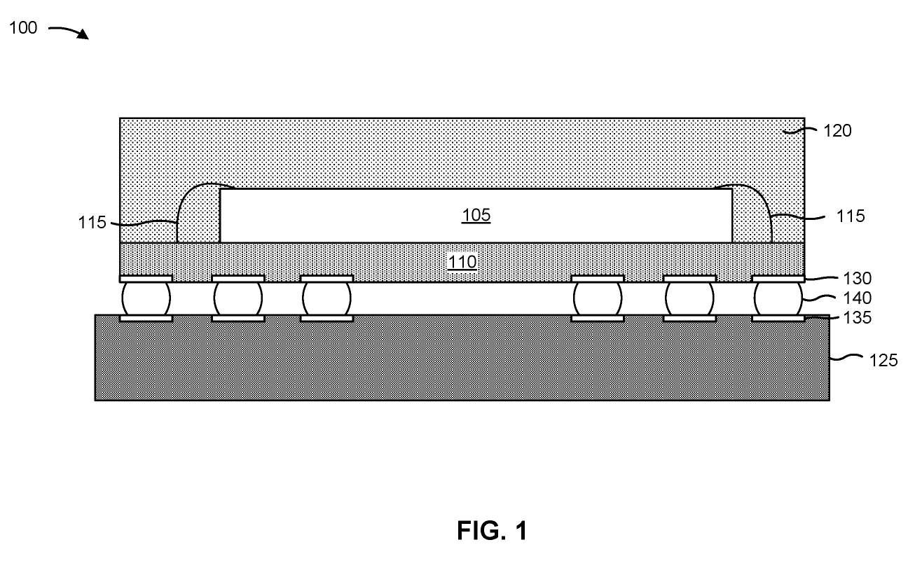

FIG. 1 is a diagram of an example apparatus 100 that may be manufactured using techniques described herein. The apparatus 100 may include any type of device or system that includes one or more semiconductor dies 105. For example, the apparatus 100 may include a memory device, a flash memory device, a NAND memory device, a NOR memory device, a random access memory (RAM) device, a read-only memory (ROM) device, a dynamic RAM (DRAM) device, a static RAM (SRAM) device, a solid state drive (SSD), a microchip, and/or a system on a chip (SoC), among other examples. In some cases, the apparatus 100 may be referred to as a semiconductor package, an assembly, a semiconductor device assembly, or an integrated assembly.

As shown in FIG. 1, the apparatus 100 may include an integrated circuit, such as a semiconductor die 105 (sometimes called a die or a chip), disposed on a circuit substrate 110. The circuit substrate 110 may be a printed circuit board (PCB) or another type of chip carrier. The circuit substrate 110 may be used as a package substrate. The semiconductor die 105 may include any type of circuit, such as an analog circuit, a digital circuit, a controller (e.g., a microcontroller), a radiofrequency (RF) circuit, a power supply, a power management circuit, an input-output (I/O) chip, an application-specific integrated circuit (ASIC), a field-programmable gate array (FPGA), and/or a memory device (e.g., a NAND memory device, a NOR memory device, a RAM device, or a ROM device). The semiconductor die 105 may be mounted on or otherwise disposed on a surface of the circuit substrate 110. Although the apparatus 100 is shown as including one semiconductor die 105 as an example, the apparatus 100 may include a different number of semiconductor dies 105, such as two or more semiconductor dies.

In some implementations, an integrated circuit may include a single semiconductor die 105, as shown in FIG. 1. In some implementations, an integrated circuit may include multiple semiconductor dies 105 (sometimes called dies) arranged in a vertical stack that forms a die stack.

In some implementations, the apparatus 100 may include multiple integrated circuits, such as multiple laterally-separated semiconductor dies or multiple laterally-separated die stacks.

As shown in FIG. 1, the semiconductor die 105 may have a first die surface (e.g., an upper surface) that faces away from the circuit substrate 110, and a second die surface (e.g., a bottom surface) that faces toward the circuit substrate 110. Bond wires 115 may be bonded to die pads arranged on the first die surface. Thus, the first die surface may be referred to as a “die pad surface.”

The apparatus 100 may include a package casing 120 that protects internal components of the apparatus 100 (e.g., the semiconductor die 105) from damage and environmental elements (e.g., particles) that can lead to malfunction of the apparatus 100. The package casing 120 may be arranged over the circuit substrate 110 to encapsulate (or at least partially encapsulate) the semiconductor die 105. The package casing 120 may fully encapsulate the semiconductor die 105 to provide optimal protection to the semiconductor die 105. The package casing 120 may be a mold compound, a plastic (e.g., an epoxy plastic), a ceramic, or another type of material depending on the functional requirements for the apparatus 100.

In some implementations, the apparatus 100 may be included as part of a higher level system (e.g., a computer, a mobile phone, a network device, an SSD, a vehicle, or an Internet of Things device), such as by electrically connecting the apparatus 100 to a circuit board 125, such as a PCB. For example, the circuit substrate 110 may be disposed on the circuit board 125 such that electrical contacts 130 (e.g., bond pads) of the circuit substrate 110 are electrically connected to electrical contacts 135 (e.g., bond pads) of the circuit board 125.

In some implementations, the circuit substrate 110 may be mounted on the circuit board 125 using solder balls 140 (e.g., arranged in a ball grid array), which may be melted to form a physical and electrical connection between the circuit substrate 110 and the circuit board 125. Additionally, or alternatively, the circuit substrate 110 may be mounted on and/or electrically connected to the circuit board 125 using another type of conductive connector, such as pins or leads. Similarly, the semiconductor die 105 may include electrical pads (e.g., bond pads) that are electrically connected to corresponding electrical pads (e.g., bond pads) of the circuit substrate 110 using electrical bonding, such as wire bonding, bump bonding, or the like. The interconnections between the semiconductor die 105, the circuit substrate 110, and the circuit board 125 enable the semiconductor die 105 to receive and transmit signals to other components of the apparatus 100 and/or the higher level system.

As indicated above, FIG. 1 is provided as an example. Other examples may differ from what is described with regard to FIG. 1.

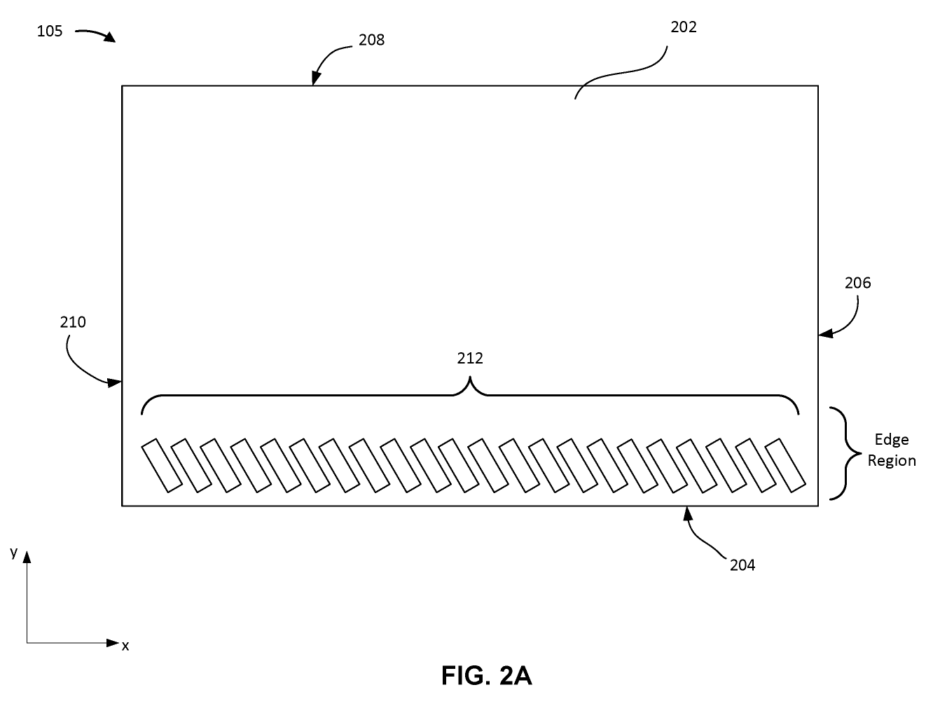

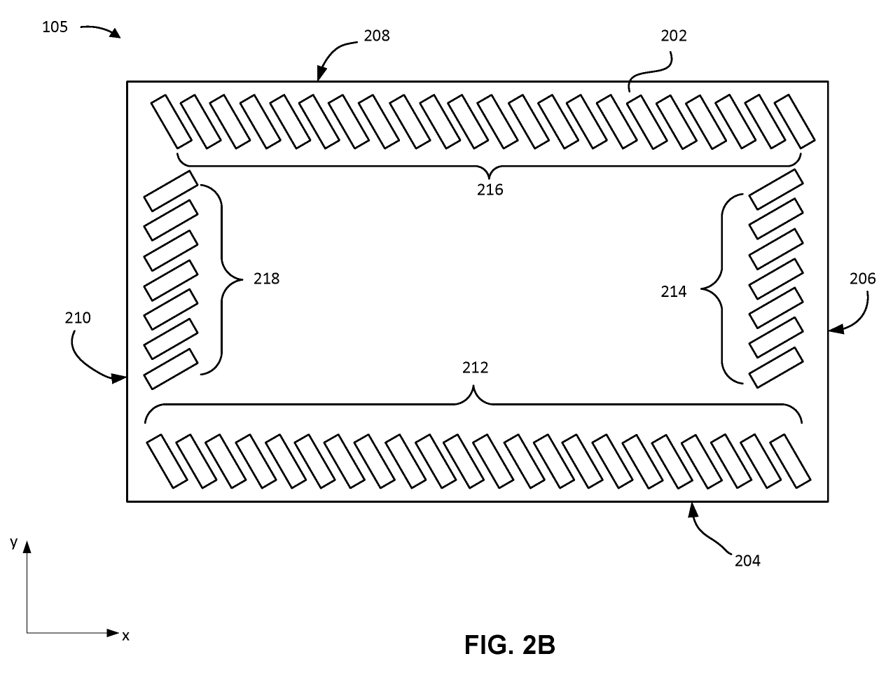

FIG. 2A is a top view of the semiconductor die 105 according to one or more implementations. The semiconductor die 105 includes a die pad surface 202 (e.g., an upper surface) and multiple die edges, including a first die edge 204, a second die edge 206, and third die edge 208, and a fourth die edge 210. The first die edge 204 and the third die edge 208 may extend parallel to a first axis (e.g., an x-axis), and the second die edge 206 and the fourth die edge 210 may extend parallel to a second axis (e.g., a y-axis) that is perpendicular to the first axis. The third die edge 208 is arranged opposite to the first die edge 204, and the fourth die edge 210 is arranged opposite to the second die edge 206.

The semiconductor die 105 includes die pads arranged on the die pad surface 202. For example, the semiconductor die 105 may include a first plurality of die pads 212 arranged on the die pad surface 202, along a first edge region of the first die edge 204. The first plurality of die pads 212 have a slanted orientation relative to the first axis and the second axis. For example, each die pad of the first plurality of die pads 212 has a longitudinal axis that extends at an angle θ between 40 and 50 degrees relative to the first die edge 204. Each die pad of the first plurality of die pads 212 has a rectangular shape that extends lengthwise along the longitudinal axis. In order to optimize a compactness and/or a quantity of the first plurality of die pads 212, the longitudinal axis of each die pad extends at a 45-degree angle relative to the first die edge.

The first plurality of die pads 212 may be arranged such that, when viewed along the second axis, a die pad of the first plurality of die pads 212, interposed laterally between two adjacent die pads of the first plurality of die pads 212, overlaps with the two adjacent die pads. For example, when viewed along the second axis, a first portion of the die pad overlaps with a first adjacent die pad of the two adjacent die pads, and a second portion of the die pad overlaps with a second adjacent die pad of the two adjacent die pads.

As indicated above, FIG. 2A is provided as an example. Other examples may differ from what is described with regard to FIG. 2A.

FIG. 2B is a top view of the semiconductor die 105 according to one or more implementations. The semiconductor die 105 is similar to the semiconductor die 105 shown in FIG. 2A, except that slanted die pads may be arranged along two or more die edges. In the example, shown in FIG. 2B, slanted die pads are arranged along edge regions of the die edges 204, 206, 208, and 210. Thus, the semiconductor die 105 may include a second plurality of die pads 214 arranged on the die pad surface 202, with the second plurality of die pads 214 having a slanted orientation relative to the first axis and the second axis. The second plurality of die pads 214 are arranged along a second edge region of the second die edge 206. Each die pad of the second plurality of die pads 214 has a longitudinal axis that extends at an angle between 40 and 50 degrees relative to the second die edge 206. The semiconductor die 105 may include a third plurality of die pads 216 arranged on the die pad surface 202, with the third plurality of die pads 216 having a slanted orientation relative to the first axis and the second axis. The third plurality of die pads 216 are arranged along a third edge region of the third die edge 208. Moreover, each die pad of the third plurality of die pads 216 has a longitudinal axis that extends at an angle between 40 and 50 degrees relative to the third die edge 208. The semiconductor die 105 may include a fourth plurality of die pads 218 arranged on the die pad surface 202, with the fourth plurality of die pads 218 having a slanted orientation relative to the first axis and the second axis. The fourth plurality of die pads 218 are arranged along a fourth edge region of the fourth die edge 210. Moreover, each die pad of the fourth plurality of die pads 218 has a longitudinal axis that extends at an angle between 40 and 50 degrees relative to the fourth die edge 210.

As indicated above, FIG. 2B is provided as an example. Other examples may differ from what is described with regard to FIG. 2B.

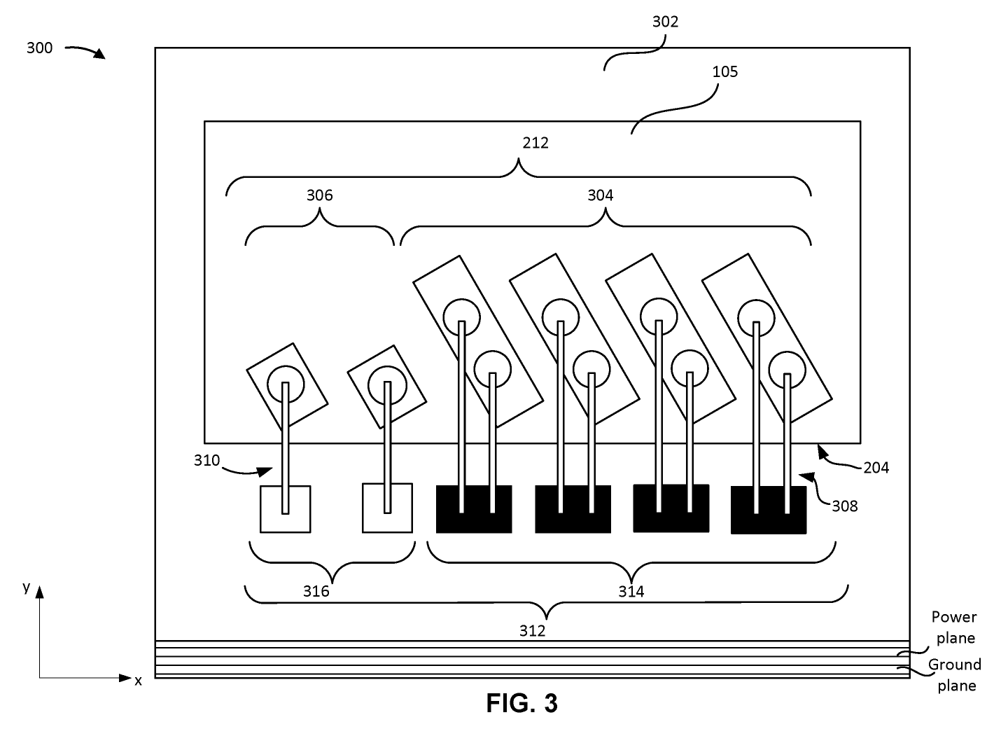

FIG. 3 is a top view of a semiconductor device assembly 300 according to one or more implementations. Semiconductor device assembly 300 may include the semiconductor die 105, as described in FIGS. 2A or 2B. The semiconductor die 105 is arranged on a die circuit substrate 302. The die circuit substrate 302 may be similar to circuit substrate 110 or may be another circuit substrate (e.g., circuit board 125). The first plurality of die pads 212 may include a plurality of supply pads 304 and a plurality of data signal pads 306. Each supply pad 304 may be configured to provide a supply connection (e.g., power or ground) to the semiconductor die 105. Each data signal pad 306 may be configured to provide a data signal connection (e.g., data signal, communication signal, or control signal, collectively referred to as information signals) to the semiconductor die 105 for transmitting and/or receiving information signals.

In addition, the semiconductor device assembly 300 may include a plurality of bond wires coupled to the first plurality of die pads 212. The plurality of bond wires may include bond wires 308 that are bonded or otherwise coupled to the supply pads 304, and bond wires 310 that are bonded or otherwise coupled to the data signal pads 306. For example, the bond wires 308 and 310 may be coupled to the first plurality of die pads 212 by ball bonds (e.g., solder balls). Each supply pad 304 may be coupled to a respective pair of bond wires 308. Two bond wires 308 coupled to a single supply pad 304 may enable higher current to flow, providing more power and an improved supply connection. In contrast, each data signal pad 306 is coupled to only a single bond wire 310, since each data signal pad 306 typically corresponds to a single data path configured for a single information signal. The data signal pads 306 may be a same size as the supply pads 304. Alternatively, the data signal pads 306 may be smaller than the supply pads 304, which may provide more area in the semiconductor die 105 for active circuitry. Active circuitry cannot be provided underneath a bond pad. Thus, by reducing a size of the data signal pads 306, there is additional area in the semiconductor die 105 for the active circuitry.

The semiconductor device assembly 300 may further include a plurality of lead fingers 312 arranged on the die circuit substrate 302. The plurality of bond wires (e.g., bond wires 308 and 310) may be coupled to the plurality of lead fingers 312 for electrically coupling the semiconductor die 105 to the die circuit substrate 302. In particular, the plurality of bond wires (e.g., bond wires 308 and 310) may be used to couple each die pad of the first plurality of die pads 212 to a respective lead finger 312. The plurality of lead fingers 312 may include a supply lead finger 314 for being connected to supply die pads 304, and data signal lead fingers 316 for being connected to data signal die pads 306. Each respective pair of bond wires 308 may be coupled to a respective lead finger of the plurality of lead fingers 312 (e.g., to a dedicated supply lead finger 314). Thus, each supply die pad 304 may be connected by two bond wires 308 to a dedicated supply lead finger 314. Each single bond wire 310 may be coupled to a dedicated data signal lead finger 316. Thus, each data signal die pad 306 may be connected by a single bond wire 310 to a dedicated data signal lead finger 316.

As indicated above, FIG. 3 is provided as an example. Other examples may differ from what is described with regard to FIG. 3.

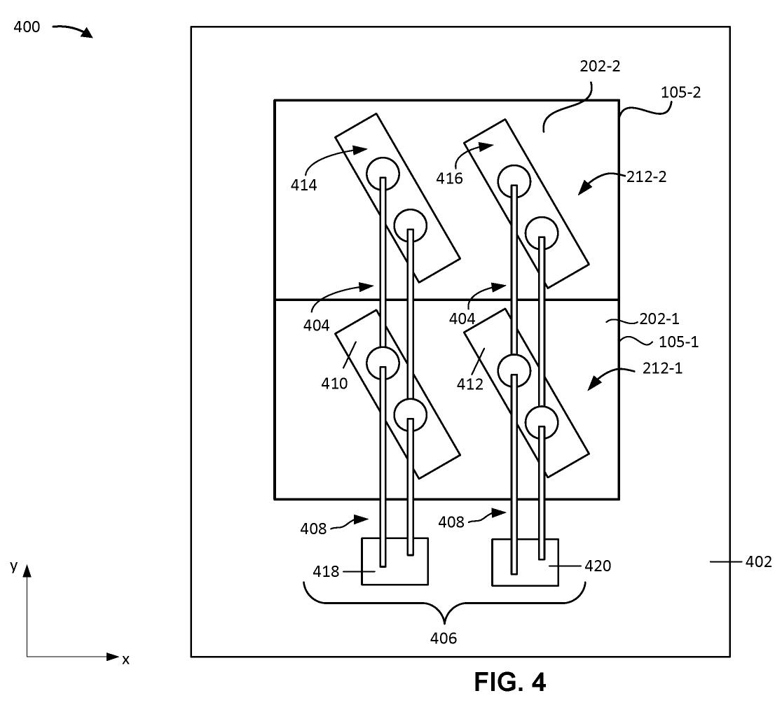

FIG. 4 is a top view of a semiconductor device assembly 400 according to one or more implementations. Semiconductor device assembly 400 may include two or more semiconductor dies 105, as described in FIGS. 2A or 2B. For example, the semiconductor device assembly 400 may include a first semiconductor die 105-1 and a second semiconductor die 105-2 arranged in a daisy-chain wire bond configuration. The daisy-chain wire bond configuration may be used to provide supply connections to the semiconductor dies 105.

The first semiconductor die 105-1 includes a first die pad surface 202-1 having a first die edge that extends parallel to a first axis and a second die edge that extends parallel to a second axis that is perpendicular to the first axis, as similarly described in connection with FIG. 2A. The first semiconductor die 105-1 may include a first plurality of die pads 212-1 arranged on the first die pad surface 202-1, the first plurality of die pads 212-1 having a slanted orientation relative to the first axis and the second axis. The first plurality of die pads 212-1 are arranged along a first edge region of the first die edge, and each die pad of the first plurality of die pads 212-1 has a longitudinal axis that extends at an angle between 40 and 50 degrees relative to the first die edge.

The second semiconductor die 105-2 includes a second die pad surface 202-2 having a third die edge that extends parallel to the first axis and a fourth die edge that extends parallel to the second axis. The second semiconductor die 105-2 may include a second plurality of die pads 212-2 arranged on the second die pad surface 202-2, with the second plurality of die pads 212-2 having a slanted orientation relative to the first axis and the second axis. The second plurality of die pads 212-2 are arranged along a third edge region of the third die edge, and each die pad of the second plurality of die pads 212-2 has a longitudinal axis that extends at an angle between 40 and 50 degrees relative to the third die edge.

The semiconductor device assembly 400 may further include a die circuit substrate 402, a first plurality of bond wires 404, a plurality of lead fingers arranged on the die circuit substrate, and a second plurality of bond wires 408. The first semiconductor die 105-1 and the second semiconductor die 105-2 may be arranged on a die circuit substrate 402.

The first plurality of bond wires 404 may be coupled to the first plurality of die pads 212-1 and the second plurality of die pads 212-2 for electrically coupling the first semiconductor die 105-1 to the second semiconductor die 105-2. For example, the first plurality of bond wires 404 may electrically couple the first semiconductor die 105-1 to the second semiconductor die 105-2 for providing supply connections (e.g., power and ground) from the first semiconductor die 105-1 to the second semiconductor die 105-2.

The second plurality of bond wires 408 may be coupled to the first plurality of die pads 212-1 and the plurality of lead fingers 406 for electrically coupling the first semiconductor die 202-1 to the plurality of lead fingers 406. For example, the second plurality of bond wires 408 may electrically couple the first semiconductor die 105-1 to the plurality of lead fingers 406 for providing supply connections (e.g., power and ground) from the plurality of lead fingers 406 to the first semiconductor die 105-1.

In some implementations, the first plurality of die pads 212-1 and the second plurality of die pads 212-2 are supply pads. The first plurality of die pads 212-1 may include a first power supply pad 410 and a first ground pad 412. The second plurality of die pads 212-2 may include a second power supply pad 414 and a second ground pad 416. The first plurality of bond wires 404 includes at least one first bond wire connected to the first power supply pad 410 and the second power supply pad 414 for providing a power connection from the first power supply pad 410 to the second power supply pad 414. In some implementations, the first plurality of bond wires 404 includes two or more first bond wires connected to the first power supply pad 410 and the second power supply pad 414 for providing the power connection from the first power supply pad 410 to the second power supply pad 414

Additionally, the first plurality of bond wires 404 includes at least one second bond wire connected to the first ground pad 412 and the second ground pad 416 for providing a ground connection from the first ground pad 412 to the second ground pad 416. In some implementations, the first plurality of bond wires 404 includes two or more second bond wires connected to the first ground pad 412 and the second ground pad 416 for providing the ground connection from the first ground pad 412 to the second ground pad 416.

The plurality of lead fingers 406 may include a power supply lead finger 418 and a grounded lead finger 420. In some examples, multiple power supply lead fingers and multiple grounded lead fingers may be provided. The die circuit substrate 402 may include a power plane coupled to the power supply lead finger 418 and a ground plane coupled to the grounded lead finger 420.

The second plurality of bond wires 408 may include at least one third bond wire connected to the first power supply pad 410 and the power supply lead finger 418 for providing a power connection from the power supply lead finger 418 to the first power supply pad 410. In some implementations, the second plurality of bond wires 408 includes two or more third bond wires connected to the first power supply pad 410 and the power supply lead finger 418 for providing the power connection from the power supply lead finger 418 to the first power supply pad 410.

Additionally, the second plurality of bond wires 408 may include at least one fourth bond wire connected to the first ground pad 412 and the grounded lead finger 420 for providing a ground connection from the grounded lead finger 420 to the first ground pad 412. In some implementations, the second plurality of bond wires 408 includes two or more fourth bond wires connected to the first ground pad 412 and the grounded lead finger 420 for providing the ground connection from the grounded lead finger 420 to the first ground pad 412.

In some implementations, the first plurality of die pads 212-1 may be arranged such that, when viewed along the second axis, a die pad of the first plurality of die pads 212-1, interposed laterally between two adjacent die pads of the first plurality of die pads 212-1, overlaps with the two adjacent die pads of the first plurality of die pads 212-1. Additionally, the second plurality of die pads 212-2 may be arranged such that, when viewed along the second axis, a die pad of the second plurality of die pads 212-2, interposed laterally between two adjacent die pads of the second plurality of die pads 212-2, overlaps with the two adjacent die pads of the second plurality of die pads 212-2.

As indicated above, FIG. 4 is provided as an example. Other examples may differ from what is described with regard to FIG. 4.

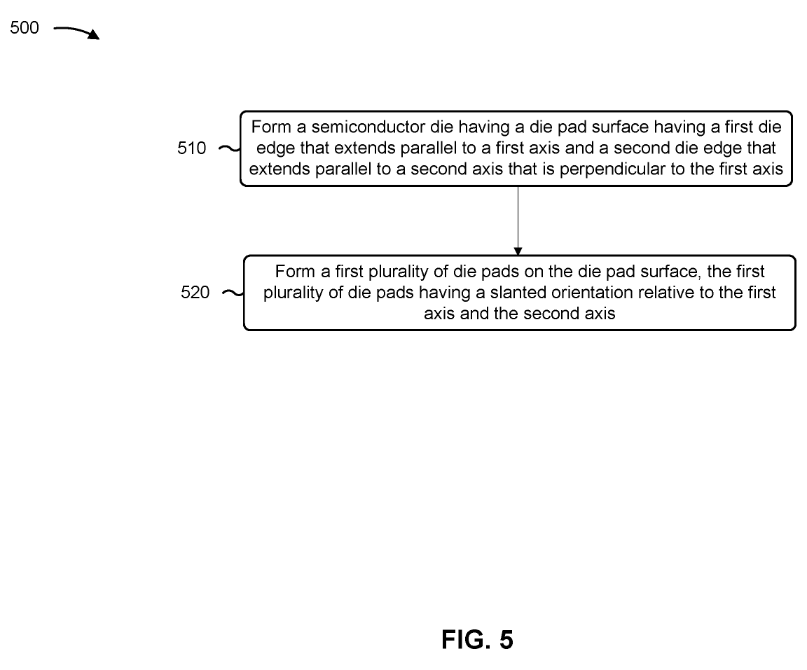

FIG. 5 is a flowchart of an example method 500 of forming an integrated assembly or semiconductor die having slanted die pads. In some implementations, one or more process blocks of FIG. 5 may be performed by various semiconductor manufacturing equipment.

As shown in FIG. 5, the method 500 may include forming a semiconductor die having a die pad surface having a first die edge that extends parallel to a first axis and a second die edge that extends parallel to a second axis that is perpendicular to the first axis (block 510). Forming the semiconductor die includes forming a first plurality of die pads on the die pad surface, the first plurality of die pads having a slanted orientation relative to the first axis and the second axis (block 520). The first plurality of die pads may be arranged along a first edge region of the first die edge, and each die pad of the first plurality of die pads may have a longitudinal axis that extends at an angle between 40 and 50 degrees relative to the first die edge.

The method 500 may include additional aspects, such as any single aspect or any combination of aspects described below and/or in connection with one or more other methods described elsewhere herein.

In a first aspect, the first plurality of die pads may be arranged such that, when viewed along the second axis, a die pad of the first plurality of die pads, interposed laterally between two adjacent die pads of the first plurality of die pads, overlaps with the two adjacent die pads.

In a second aspect, alone or in combination with the first aspect, the method 500 includes bonding a plurality of bond wires to the first plurality of die pads. The first plurality of die pads may include a plurality of supply pads, and each supply pad may be coupled to a respective pair of bond wires of the plurality of bond wires.

In a third aspect, alone or in combination with one or more of the first and second aspects, the method 500 includes arranging the semiconductor die on a die circuit substrate, arranging a plurality of lead fingers on the die circuit substrate, and bonding the plurality of bond wires to the plurality of lead fingers for electrically coupling the semiconductor die to the die circuit substrate. Each respective pair of bond wires may be coupled to a respective lead finger of the plurality of lead fingers.

Although FIG. 5 shows example blocks of the method 500, in some implementations, the method 500 may include additional blocks, fewer blocks, different blocks, or differently arranged blocks than those depicted in FIG. 5. In some implementations, the method 500 may include forming the semiconductor die 105, the semiconductor device assembly 300, and/or the semiconductor device assembly 400.

In some implementations, a semiconductor device assembly includes a semiconductor die comprising: a die pad surface having a first die edge that extends parallel to a first axis and a second die edge that extends parallel to a second axis that is perpendicular to the first axis; and a first plurality of die pads arranged on the die pad surface, the first plurality of die pads having a slanted orientation relative to the first axis and the second axis, wherein the first plurality of die pads are arranged along a first edge region of the first die edge, and wherein each die pad of the first plurality of die pads has a longitudinal axis that extends at an angle between 40 and 50 degrees relative to the first die edge.

In some implementations, a semiconductor device assembly includes a first semiconductor die comprising: a first die pad surface having a first die edge that extends parallel to a first axis and a second die edge that extends parallel to a second axis that is perpendicular to the first axis; and a first plurality of die pads arranged on the first die pad surface, the first plurality of die pads having a slanted orientation relative to the first axis and the second axis, wherein the first plurality of die pads are arranged along a first edge region of the first die edge, and wherein each die pad of the first plurality of die pads has a longitudinal axis that extends at an angle between 40 and 50 degrees relative to the first die edge; a second semiconductor die comprising: a second die pad surface having a third die edge that extends parallel to the first axis and a fourth die edge that extends parallel to the second axis; and a second plurality of die pads arranged on the second die pad surface, the second plurality of die pads having a slanted orientation relative to the first axis and the second axis, wherein the second plurality of die pads are arranged along a third edge region of the third die edge, and wherein each die pad of the second plurality of die pads has a longitudinal axis that extends at an angle between 40 and 50 degrees relative to the third die edge; and a first plurality of bond wires coupled to the first plurality of die pads and the second plurality of die pads for electrically coupling the first semiconductor die to the second semiconductor die.

In some implementations, a method of manufacturing a semiconductor device assembly includes forming a semiconductor die having a die pad surface having a first die edge that extends parallel to a first axis and a second die edge that extends parallel to a second axis that is perpendicular to the first axis, wherein forming the semiconductor die includes forming a first plurality of die pads on the die pad surface, the first plurality of die pads having a slanted orientation relative to the first axis and the second axis, wherein the first plurality of die pads are arranged along a first edge region of the first die edge, and wherein each die pad of the first plurality of die pads has a longitudinal axis that extends at an angle between 40 and 50 degrees relative to the first die edge.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element’s relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.”

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a + b, a + c, b + c, and a + b + c, as well as any combination with multiples of the same element (e.g., a + a, a + a + a, a + a + b, a + a + c, a + b + b, a + c + c, b + b, b + b + b, b + b + c, c + c, and c + c + c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A semiconductor device assembly, comprising:
a semiconductor die comprising:
a die pad surface having a first die edge that extends parallel to a first axis and a second die edge that extends parallel to a second axis that is perpendicular to the first axis; and
a first plurality of die pads arranged on the die pad surface, the first plurality of die pads having a slanted orientation relative to the first axis and the second axis,
wherein the first plurality of die pads are arranged along a first edge region of the first die edge, and
wherein each die pad of the first plurality of die pads has a longitudinal axis that extends at an angle between 40 and 50 degrees relative to the first die edge.

2. The semiconductor device assembly of claim 1, wherein the first plurality of die pads are arranged such that, when viewed along the second axis, a die pad of the first plurality of die pads, interposed laterally between two adjacent die pads of the first plurality of die pads, overlaps with the two adjacent die pads.

3. The semiconductor device assembly of claim 2, wherein, when viewed along the second axis, a first portion of the die pad overlaps with a first adjacent die pad of the two adjacent die pads, and a second portion of the die pad overlaps with a second adjacent die pad of the two adjacent die pads.

4. The semiconductor device assembly of claim 1, wherein the longitudinal axis of each die pad extends at a 45-degree angle relative to the first die edge.

5. The semiconductor device assembly of claim 1, wherein each die pad of the first plurality of die pads has a rectangular shape.

6. The semiconductor device assembly of claim 1, wherein the semiconductor die further comprises a second plurality of die pads arranged on the die pad surface, the second plurality of die pads having a slanted orientation relative to the first axis and the second axis,
wherein the second plurality of die pads are arranged along a second edge region of the second die edge, and
wherein each die pad of the second plurality of die pads has a longitudinal axis that extends at an angle between 40 and 50 degrees relative to the second die edge.

7. The semiconductor device assembly of claim 1, wherein the die pad surface has a third die edge arranged opposite to the first die edge and extends parallel to the first axis,
wherein the semiconductor die further comprises a third plurality of die pads arranged on the die pad surface, the third plurality of die pads having a slanted orientation relative to the first axis and the second axis,
wherein the third plurality of die pads are arranged along a third edge region of the third die edge, and
wherein each die pad of the third plurality of die pads has a longitudinal axis that extends at an angle between 40 and 50 degrees relative to the third die edge.

8. The semiconductor device assembly of claim 1, further comprising:
a plurality of bond wires coupled to the first plurality of die pads,
wherein the first plurality of die pads includes a plurality of supply pads, and
wherein each supply pad of the plurality of supply pads is coupled to a respective pair of bond wires of the plurality of bond wires.

9. The semiconductor device assembly of claim 8, further comprising:
a die circuit substrate on which the semiconductor die is arranged; and
a plurality of lead fingers arranged on the die circuit substrate,
wherein the plurality of bond wires are coupled to the plurality of lead fingers for electrically coupling the semiconductor die to the die circuit substrate, and
wherein each respective pair of bond wires is coupled to a respective lead finger of the plurality of lead fingers.

10. The semiconductor device assembly of claim 8, wherein the first plurality of die pads includes a plurality of data signal pads, and
wherein each data signal pad of the plurality of data signal pads is coupled to only a single bond wire of the plurality of bond wires.

11. The semiconductor device assembly of claim 10, further comprising:
a die circuit substrate on which the semiconductor die is arranged; and
a plurality of lead fingers arranged on the die circuit substrate,
wherein the plurality of bond wires are coupled to the plurality of lead fingers for electrically coupling the semiconductor die to the die circuit substrate,
wherein each respective pair of bond wires is coupled to a dedicated supply lead finger of the plurality of lead fingers, and
wherein each single bond wire is coupled to a dedicated data signal lead finger of the plurality of lead fingers.

12. The semiconductor device assembly of claim 1, wherein the semiconductor die is a memory die.

13. A semiconductor device assembly, comprising:
a first semiconductor die comprising:
a first die pad surface having a first die edge that extends parallel to a first axis and a second die edge that extends parallel to a second axis that is perpendicular to the first axis; and
a first plurality of die pads arranged on the first die pad surface, the first plurality of die pads having a slanted orientation relative to the first axis and the second axis,
wherein the first plurality of die pads are arranged along a first edge region of the first die edge, and
wherein each die pad of the first plurality of die pads has a longitudinal axis that extends at an angle between 40 and 50 degrees relative to the first die edge;
a second semiconductor die comprising:
a second die pad surface having a third die edge that extends parallel to the first axis and a fourth die edge that extends parallel to the second axis; and
a second plurality of die pads arranged on the second die pad surface, the second plurality of die pads having a slanted orientation relative to the first axis and the second axis,
wherein the second plurality of die pads are arranged along a third edge region of the third die edge, and
wherein each die pad of the second plurality of die pads has a longitudinal axis that extends at an angle between 40 and 50 degrees relative to the third die edge; and
a first plurality of bond wires coupled to the first plurality of die pads and the second plurality of die pads for electrically coupling the first semiconductor die to the second semiconductor die.

14. The semiconductor device assembly of claim 13, further comprising:
a die circuit substrate on which the first semiconductor die and the first semiconductor die are arranged;
a plurality of lead fingers arranged on the die circuit substrate; and
a second plurality of bond wires coupled to the first plurality of die pads and the plurality of lead fingers for electrically coupling the first semiconductor die to the plurality of lead fingers.

15. The semiconductor device assembly of claim 13, wherein the first plurality of die pads and the second plurality of die pads are supply pads,
wherein the first plurality of die pads includes a first power supply pad and a first ground pad,
wherein the second plurality of die pads includes a second power supply pad and a second ground pad,
wherein the first plurality of bond wires includes at least one first bond wire connected to the first power supply pad and the second power supply pad for providing a power connection from the first power supply pad to the second power supply pad, and
wherein the first plurality of bond wires includes at least one second bond wire connected to the first ground pad and the second ground pad for providing a ground connection from the first ground pad to the second ground pad.

16. The semiconductor device assembly of claim 15, further comprising:
a die circuit substrate on which the first semiconductor die and the first semiconductor die are arranged;
a plurality of lead fingers arranged on the die circuit substrate, the plurality of lead fingers including a power supply lead finger and a grounded lead finger; and
a second plurality of bond wires coupled to the first plurality of die pads and the plurality of lead fingers for electrically coupling the first semiconductor die to the plurality of lead fingers.

17. The semiconductor device assembly of claim 16, wherein the die circuit substrate comprises a power plane coupled to the power supply lead finger and a ground plane coupled to the grounded lead finger.

18. The semiconductor device assembly of claim 16, wherein the second plurality of bond wires includes at least one third bond wire connected to the first power supply pad and the power supply lead finger for providing a power connection from the power supply lead finger to the first power supply pad, and
wherein the second plurality of bond wires includes at least one fourth bond wire connected to the first ground pad and the grounded lead finger for providing a ground connection from the grounded lead finger to the first ground pad.

19. The semiconductor device assembly of claim 18, wherein the second plurality of bond wires includes two or more third bond wires connected to the first power supply pad and the power supply lead finger for providing the power connection from the power supply lead finger to the first power supply pad, and
wherein the second plurality of bond wires includes two or more fourth bond wires connected to the first ground pad and the grounded lead finger for providing the ground connection from the grounded lead finger to the first ground pad.

20. The semiconductor device assembly of claim 15, wherein the first plurality of bond wires includes two or more first bond wires connected to the first power supply pad and the second power supply pad for providing the power connection from the first power supply pad to the second power supply pad, and
wherein the first plurality of bond wires includes two or more second bond wires connected to the first ground pad and the second ground pad for providing the ground connection from the first ground pad to the second ground pad.

21. The semiconductor device assembly of claim 13, wherein the first plurality of die pads are arranged such that, when viewed along the second axis, a die pad of the first plurality of die pads, interposed laterally between two adjacent die pads of the first plurality of die pads, overlaps with the two adjacent die pads of the first plurality of die pads, and
wherein the second plurality of die pads are arranged such that, when viewed along the second axis, a die pad of the second plurality of die pads, interposed laterally between two adjacent die pads of the second plurality of die pads, overlaps with the two adjacent die pads of the second plurality of die pads.

22. A method of manufacturing a semiconductor device assembly, the method comprising:
forming a semiconductor die having a die pad surface having a first die edge that extends parallel to a first axis and a second die edge that extends parallel to a second axis that is perpendicular to the first axis,
wherein forming the semiconductor die includes forming a first plurality of die pads on the die pad surface, the first plurality of die pads having a slanted orientation relative to the first axis and the second axis,
wherein the first plurality of die pads are arranged along a first edge region of the first die edge, and
wherein each die pad of the first plurality of die pads has a longitudinal axis that extends at an angle between 40 and 50 degrees relative to the first die edge.

23. The method of claim 22, wherein the first plurality of die pads are arranged such that, when viewed along the second axis, a die pad of the first plurality of die pads, interposed laterally between two adjacent die pads of the first plurality of die pads, overlaps with the two adjacent die pads.

24. The method of claim 22, further comprising:
bonding a plurality of bond wires to the first plurality of die pads,
wherein the first plurality of die pads includes a plurality of supply pads, and
wherein each supply pad of the plurality of supply pads is coupled to a respective pair of bond wires of the plurality of bond wires.

25. The method of claim 24, further comprising:
arranging the semiconductor die on a die circuit substrate;
arranging a plurality of lead fingers on the die circuit substrate; and
bonding the plurality of bond wires to the plurality of lead fingers for electrically coupling the semiconductor die to the die circuit substrate,
wherein each respective pair of bond wires is coupled to a respective lead finger of the plurality of lead fingers.
